(19) United States
(12) Patent Application Publication
(10) Pub. No.: US 2006/0071252 A1
(43) Pub. Date: Apr. 6, 2006

(54) Solid-state imaging apparatus

(75) Inventor: Toru Kondo, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: OLYMPUS CORPORATION, Tokyo (JP)

(21) Appl. No.: 11/230,517

(22) Filed: Sep. 21, 2005

(30) Foreign Application Priority Data
Sep. 27, 2004 (JP) 2004-278671

(51) Int. Cl. H01L 31/113; H01L 31/0203; H04N 5/335

(52) U.S. Cl. 257/291; 348/294; 348/308; 257/434

(57) ABSTRACT

Disclosed herein is a solid-state imaging apparatus including: a pixel section having a plurality of pixels disposed two-dimensionally in rows and columns, each pixel containing a photoelectric conversion section and an amplifying section for amplifying output of the photoelectric conversion section to output pixel signals; a first scanning section for selecting a row to be read out of the pixel section; a noise suppressing section for effecting pixel-by-pixel noise suppression of the pixel signals; a second scanning section for selecting a column to be read out of the pixel section to cause the pixel signals processed through the noise suppressing section be outputted from a horizontal signal line; a first reference potential line for supplying a reference potential; and a second reference potential line separate from the first reference potential line. At least the second scanning section of the first and second scanning sections is constituted of a plurality of units in cascade connection where each one unit includes: a scanning circuit having a function device group formed on a first well region connected to the first reference potential line, for supplying signals to the pixel section through an output line to effect the selection process thereof; and a reference potential fixing circuit having a switch device connected at one end to the output line and at the other end to the second reference potential line, and a control circuit for controlling the switch device.

### This application claims benefit of Japanese-Patent Application No. 2004-278671 filed in Japan on Sep. 27, 2004, the contents of which are incorporated by this reference.

### BACKGROUND OF THE INVENTION

The present invention relates to solid-state imaging apparatus, and more particularly relates to solid-state imaging apparatus using amplified MOS sensor.

FIG. 1A is a circuit diagram showing an example of construction of prior-art solid-state imaging apparatus using MOS image sensor. The solid-state imaging apparatus includes: unit pixels 1 each having a photodiode PD₁ serving as a photoelectric conversion section, an amplifying transistor M₁ for amplifying detection signals of the photodiode PD₁, a reset transistor M₂ for resetting detection signals of the photodiode PD₁, a row select transistor M₃ for selecting each row, and a pixel power supply VDD; a vertical scanning section 2 for driving a pixel section consisting of a plurality of unit pixels 1 that are arranged in a matrix; a vertical signal line 3 for outputting detection signals of unit pixel 1; a bias transistor M₅ for causing a flow of constant current through the vertical signal line 3; a bias current adjusting voltage line VBIAS for determining a current value of the bias transistor; clamp capacitor C₁₁ connected to the vertical signal line 3; hold capacitor C₁₂ for retaining the amount of change in voltage of the vertical signal line 3; a sample hold transistor M₁₁ for connecting between clamp capacitor C₁₁ and hold capacitor C₁₂; a clamp transistor M₁₂ for clamping the clamp capacitor C₁₁ and hold capacitor C₁₂ to a predetermined voltage; a column select transistor M₁₃ for reading signals from the hold capacitor C₁₂ of each column, connected at one end terminal thereof to the hold capacitor C₁₂; a horizontal signal line 15 connected to the other end terminal of the column select transistor M₁₃; an output amplifier 16; and a horizontal scanning section 20 for driving the column select transistor M₁₃. It should be noted that the clamp capacitor C₁₁, hold capacitor C₁₂, sample hold transistor M₁₁, and clamp transistor M₁₂ form a noise suppressing section 10.

The operation of the prior-art solid-state imaging apparatus having the above described construction will now be described by way of a fundamental drive timing chart shown in FIG. 1B. When a row select pulse φROW1 of a first unit pixel row outputted from the vertical scanning section 2 is driven to H (high) level, the row select transistor M₃ is turned ON so that signal voltage of the unit pixel 1 is outputted onto the vertical signal line 3. At this time, the sample hold transistor M₁₁ and clamp transistor M₁₂ are turned ON by bringing clamp control pulse φCLP to H level and sample hold control pulse φSH to H level so as to fix the clamp capacitor C₁₁ and hold capacitor C₁₂ to a reference potential VREF.

Next, the connecting line between clamp capacitor C₁₁ and hold capacitor C₁₂ is brought into a floating state by driving clamp control pulse φCLP to L (low) level to turn OFF the clamp transistor M₁₂. Subsequently, reset control pulse φRES1 of the first unit pixel row is driven to H level to turn ON the reset transistor M₂ so as to reset the detection signal of photodiode PD₁. Then, by driving the reset control pulse φRES1 back to L level again, the reset transistor M₂ is turned OFF. At this time, voltage change ΔVsig between before and after the resetting of photodiode PD₁ occurs on the vertical signal line 3 and accumulates at the hold capacitor C₁₂ through the clamp capacitor C₁₁ and sample hold transistor M₁₁.

Subsequently, the signal component of photodiode PD₁ is retained at the hold capacitor C₁₂ by driving the sample hold control pulse φSH to L level so as to turn OFF the sample hold transistor M₁₁.

Finally, the signal component retained at the hold capacitor C₁₂ is sequentially read out to the horizontal signal line 15 through the column select transistor M₁₃ by the means of horizontal select pulses φH1 and φH2 outputted from the horizontal scanning section 20 and is fetched from the output amplifier 16.

FIG. 2 is a circuit diagram showing an example of construction of the horizontal scanning section 20 in the solid-state imaging apparatus shown in FIG. 1A. This example is a portion of the construction where the horizontal scanning section is constituted only of NMOS transistors and capacitors, disclosed for example in Japanese Patent Publication Hei-5-84967.

In this example, an input terminal φST is connected to the gate of MOS transistor M₃₂ and gate of MOS transistor M₄₂ through MOS transistor M₃₁. A bootstrap capacitor C₃₁ is connected between gate and source of the MOS transistor M₃₂. The source of MOS transistor M₃₂ is connected to a ground line GND through MOS transistor M₄₃. Further the source of MOS transistor M₃₂ is connected to the gate of MOS transistor M₅₂ and to the gate of MOS transistor M₆₂ through MOS transistor M₅₁. A bootstrap capacitor C₅₁ is connected between source and gate of the MOS transistor M₅₂. Further the source of MOS transistor M₅₂ is connected to the ground line GND through MOS transistor M₆₃. Furthermore, the source of MOS transistor M₅₂ is connected to the circuit of the next stage.

A clock terminal φ1 is connected to the respective gates of the MOS transistors M₃₁ and M₄₁, and to the drain of MOS transistor M₅₂, and clock terminal φ2 is connected to the respective gates of the MOS transistors M₅₁ and M₆₁, and to the drain of MOS transistor M₃₂. A power supply line VDD is connected to the respective drains of the MOS transistors M₄₁ and M₆₁. Further the respective sources of the MOS transistors M₄₁ and M₆₁ are connected to the respective gates of the MOS transistors M₄₃ and M₆₃ and to the respective drains of the MOS transistors M₄₂ and M₆₂ while the respective sources of the MOS transistors M₄₂ and M₆₂ are connected to the ground line GND.

The circuit constituted of the transistors and bootstrap capacitors constructed as the above is repeatedly connected in a sequence. It should be noted in FIG. 2 that: OUT₁, OUT₂, . . . , are output lines; G₃₂, G₅₂, . . . , respectively refer to gate lines of the MOS transistors M₃₂, M₅₂, . . . ; C_{S1} is parasitic capacitance added to the gate lines G₃₂, G₅₂, . . . , not contributing to the bootstrap effect; C_{S2} is parasitic capacitance not contributing to bootstrap effect, caused by gate of the MOS transistors M₄₂, M₆₂, . . . ; and numerals 40, 60, 140, 160 refer to reference potential fixing circuits.

FIG. 3 is a timing chart for explaining a fundamental operation of the horizontal scanning section shown in FIG. 2. Signals indicated by φ1, φ2, and φST of FIG. 3 are respectively given to clock terminals φ1 and φ2, and input terminal φST in the horizontal scanning section of the circuit construction shown in FIG. 2. Here H level potential of input terminal φST, clock terminals φ1 and φ2 is defined as V_{H} and threshold value of all the MOS transistors as Vₜₕ.

First, when input terminal φST and clock terminal φ1 are driven to H level, MOS transistor M₃₁ becomes conductive. Since H level of the input terminal φST is thereby transmitted through MOS transistor M₃₁ so that charges are accumulated at the bootstrap capacitor C₃₁, potential at the gate line G₃₂ of MOS transistor M₃₂ becomes H level as indicated by V_{G32} of FIG. 3. Supposing H level potential of the gate line G₃₂ of MOS transistor M₃₂ at this time as V_{H}′:
V_{H}′=V_{H}−Vₜₕ (1)

Further, MOS transistor M₃₂ becomes conductive and L level of clock terminal φ2 is outputted to potential V_{OUT1} of the output line OUT₁ due to the fact that potential V_{G32} at the gate line G₃₂ of MOS transistor M₃₂ is brought to H level. At this time, since MOS transistor M₄₂ also becomes conductive, the gate line G₄₃ of MOS transistor M₄₃ is connected to the ground line GND as indicated by V_{G43} of FIG. 3 so that MOS transistor M₄₃ is cut off.

Next, when clock terminal φ1 is changed to L level and in addition clock terminal φ2 becomes H level after changing clock terminal φST to low level, potential V_{G32} of the gate line G₃₂ of MOS transistor M₃₂ rises by V_{A} as expressed in the following formula (2) through the bootstrap capacitor C₃₁.
V_{A}={C₃₁/(C₃₁+C_{S1}+C_{S2})}V_{H} (2)
where C_{S1}, C_{S2} respectively are parasitic capacitance not contributing to the bootstrap effect, caused by the respective gates of MOS transistors M₃₂, M₄₂. Accordingly, potential V_{G32} of the gate line G₃₂ of MOS transistor M₃₂ is as expressed in the following formula (3).
V_{G32}=V_{H}′+{C₃₁/(C₃₁+C_{S1}+C_{S2})}V_{H} (3)

At this time, if:
V_{G32}−Vₜₕ≧V_{H} (4)

H level of the clock terminal φ2 is extracted at the source of MOS transistor M₃₂. Here, since potential V_{G43} of the gate line G₄₃ of MOS transistor M₄₃ is continuously connected to the ground line GND, MOS transistor M₄₃ is in its cut-off state. Since the ground line GND is thereby disconnected from the output line OUT₁, it does not cause-an adverse effect on the output line OUT₁. Accordingly, an identical pulse as clock terminal φ2 is fetched at the output line OUT₁ as indicated by V_{OUT1} of FIG. 3. At the same time, since MOS transistor M₅₁ becomes conductive in synchronization with H level of clock terminal φ2, charges are accumulated at the bootstrap capacitor C₅₁. Thus the potential of the gate line G₅₂ of MOS transistor M₅₂ becomes H level as indicated by V_{G52} of FIG. 3.

Next, when clock terminal φ1 becomes H level again, potential V_{G52} of the gate line G₅₂ of MOS transistor M₅₂ is raised from H-level potential V_{H} of clock terminal φ1 through the bootstrap capacitor C₅₁. An H level of clock terminal φ1 is thereby extracted to the source of MOS transistor M₅₂. Accordingly, an identical pulse as clock terminal φ1 is fetched at the output line OUT₂ as indicated by V_{OUT2} of FIG. 3.

Further, since the input terminal φST at this time is L level, potential V_{G32} of the gate line G₃₂ of MOS transistor M₃₂ becomes L level so that MOS transistor M₄₂ is brought into its cut-off state. Since MOS transistor M₄₁ at this time is conductive, potential V_{G43} of-the gate line G₄₃ of MOS transistor M₄₃ becomes H level. MOS transistor M₄₃ thereby becomes conductive so that potential V_{OUT1} of the output line OUT₁ is connected to the ground line GND.

Similarly, of the next stage of FIG. 2, potentials at the gate line G₁₃₂ of MOS transistor M₁₃₂, gate line G₁₄₃ of MOS transistor M₁₄₃, output line OUT₃, gate line G₁₅₂ of MOS transistor M₁₅₂, gate line G₁₆₃ of MOS transistor M₁₆₃, and output line OUT₄ are as indicated by V_{G132}, G_{G143}, V_{OUT3}, V_{G152}, V_{G163} and V_{OUT4} of FIG. 3, respectively.

Accordingly, at the horizontal scanning section of this circuit construction, H level signal of the input terminal φST is sequentially transmitted so that pulse is sequentially fetched from the output lines OUT₁, OUT₂, OUT₃ and OUT₄. The column select transistor M₁₃ in the solid-state imaging apparatus shown in FIG. 1A is driven by these pulses to read signals out to the horizontal signal line 15.

### SUMMARY OF THE INVENTION

It is an object of the present invention to provide a solid-state imaging apparatus in which output noise of a scanning section constituted only of NMOS transistors and capacitors is made smaller so that the signal quality thereof is improved.

A solid-state imaging apparatus according to a first aspect of the invention includes: a pixel section having a plurality of pixels disposed two-dimensionally in rows and columns, each pixel containing a photoelectric conversion section and an amplifying section for amplifying output of the photoelectric conversion section to output pixel signals; a first scanning section for selecting a row to be read out of the pixel section; a noise suppressing section for effecting pixel-by-pixel noise suppression of the pixel signals; a second scanning section for selecting a column to be read out of the pixel section to cause the pixel signals processed through the noise suppressing section be outputted from a horizontal signal line; a first reference potential line for supplying a reference potential; and a second reference potential line separate from the first reference potential line. At least the second scanning section of the first and second scanning sections is constituted of a plurality of units in cascade connection where each one unit includes: a scanning circuit having a function device group formed on a first well region connected to the first reference potential line, for supplying signals for effecting the selection process to the pixel section through an output line; and a reference potential fixing circuit having a switch device connected at one end to the output line and at the other end to the second reference potential line, and a control circuit for controlling the switch device.

In a second aspect of the invention, the scanning circuit in the solid-state imaging apparatus according to the first aspect includes transistors in the function device group, and the transistors are solely of a one conducting type.

In a third aspect of the invention, the scanning circuit in the solid-state imaging apparatus according to the first aspect includes: a first scanning circuit having a first switch device connected at one end to the output line of preceding one of the units with connection at the other end thereof being controlled by a first control pulse, a first source follower connected at gate to the other end of the first switch device with receiving at the drain a second control pulse having a phase different from the first control pulse and connected at source to a first output line, and a first capacitance component connected between gate and source of the first source follower; and a second scanning circuit having a second switch device connected at one end to the source of the first source follower with connection at the other end thereof being controlled by the second control pulse, a second source follower connected at gate to the other end of the second switch device with receiving at the drain the first control pulse and connected at source to a second output line and to the one end of the first switch of succeeding one of the units, and a-second capacitance component connected between gate and source of the-second source follower. The reference potential fixing circuit includes: a first reference potential fixing circuit having a third switch device serving as the switch device connected at one end to the first output line and at the other end to the second reference potential line, and a first control circuit serving as the control circuit for controlling the third switch device in accordance with the source output level of the second source follower of the preceding unit; and a second reference potential fixing circuit having a fourth switch device serving as the switch device connected at one end to the second output line and at the other end to the second reference potential line, and a second control circuit serving as the control circuit for controlling the fourth switch device in accordance with level of signals supplied from the source of the first source follower.

In a fourth aspect of the invention, the first and second reference potential fixing circuits in the solid-state imaging apparatus according to the third aspect are formed on a second well region connected to the second reference potential line, separate from the first well.

In a fifth aspect of the invention, the first and second control circuits in the solid-state imaging apparatus according to the third aspect are formed on the first well region.

In a sixth aspect of the invention, the third and fourth switch devices of the solid-state imaging apparatus according to the third aspect are formed on a second well region connected to the second reference potential line, separate from the first well.

In a seventh aspect of the invention, the first reference potential line and the second reference potential line in the solid-state imaging apparatus according to the third aspect are connected to different pads from each other.

In an eighth aspect of the invention, the first reference potential line and the second reference potential line in the solid-state imaging apparatus according to the third aspect are connected to the same one pad in the vicinity of the pad.

### BRIEF DESCRIPTION OF THE DRAWINGS

FIGS. 1A and 1B are a circuit diagram showing an example of construction of prior-art solid-state imaging apparatus and a timing chart for explaining operation thereof, respectively.

FIG. 2 is a-circuit diagram showing construction of a horizontal scanning section in the prior-art example shown in FIG. 1A.

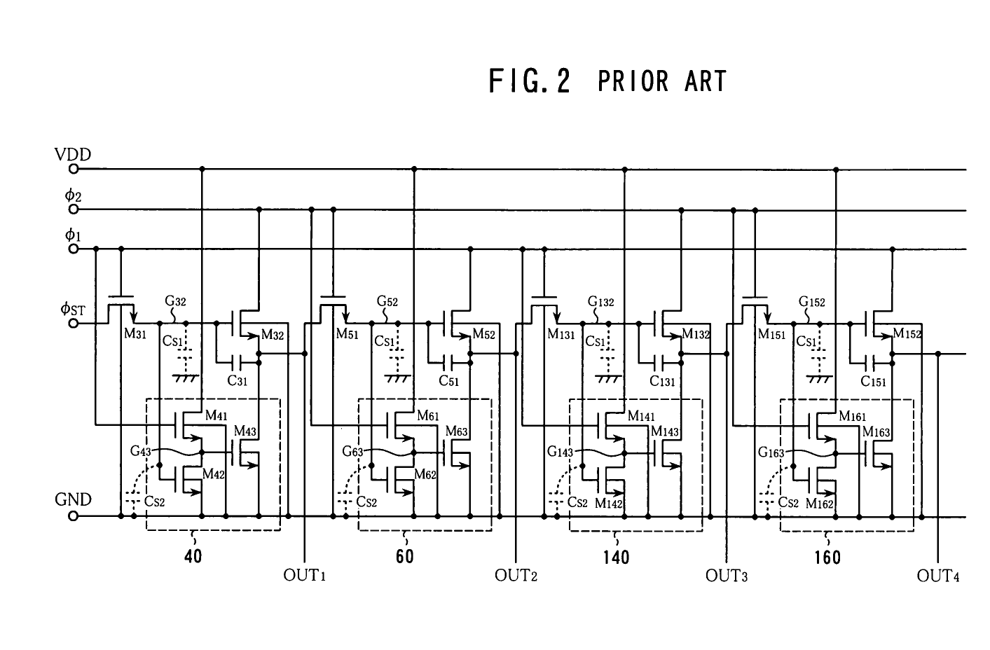

FIG. 3 is a timing chart for explaining a fundamental operation of the horizontal scanning section shown in FIG. 2.

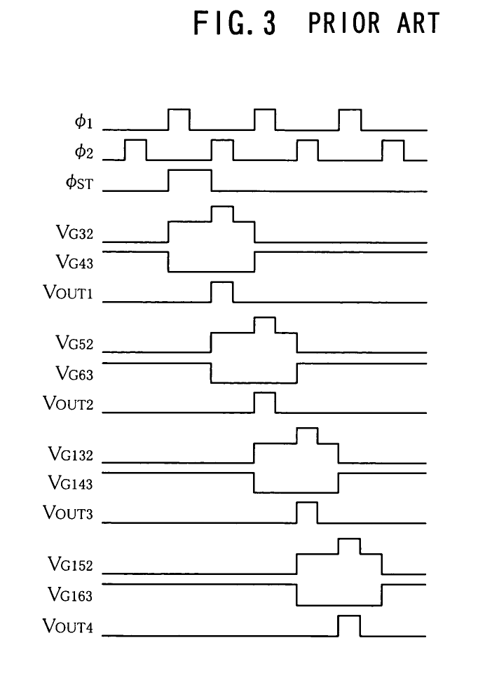

FIGS. 4A and 4B are a circuit diagram showing construction of a first embodiment of the solid-state imaging apparatus according to the invention and a timing chart for explaining operation thereof, respectively.

FIG. 5 is a circuit diagram showing a detailed construction of the horizontal scanning section in the first embodiment shown in FIG. 4A.

FIG. 6 is a timing chart for explaining operation of the horizontal scanning section shown in FIG. 5.

FIG. 7 is a conceptual drawing showing partially in section the manner of forming the horizontal scanning section shown in FIG. 5 on a single semiconductor substrate.

FIGS. 8A and 8B are circuit diagrams showing two modes where pads for external input are added to the horizontal scanning section shown in FIG. 5.

FIGS. 9A and 9B are circuit diagrams showing two modifications of each of the reference potential fixing circuits at the horizontal scanning section shown in FIG. 5.

FIG. 10 is a circuit diagram showing construction of the horizontal scanning section of a solid-state imaging apparatus according to a second embodiment of the invention.

FIG. 11 is a timing chart for explaining operation of the horizontal scanning section shown in FIG. 10.

FIG. 12 is a conceptual drawing showing partially in section the manner of forming the horizontal scanning section shown in FIG. 10 on a single semiconductor substrate.

FIGS. 13A and 13B are circuit diagrams showing two modes where pads for external input are added to the horizontal scanning section shown in FIG. 10.

FIGS. 14A and 14B are circuit diagrams showing two modifications of each of the reference potential fixing circuits at the horizontal scanning section shown in FIG. 10.

### DESCRIPTION OF THE PREFERRED EMBODIMENTS

Some embodiments according to the present invention will be described below with reference to the drawings.

### Embodiment 1

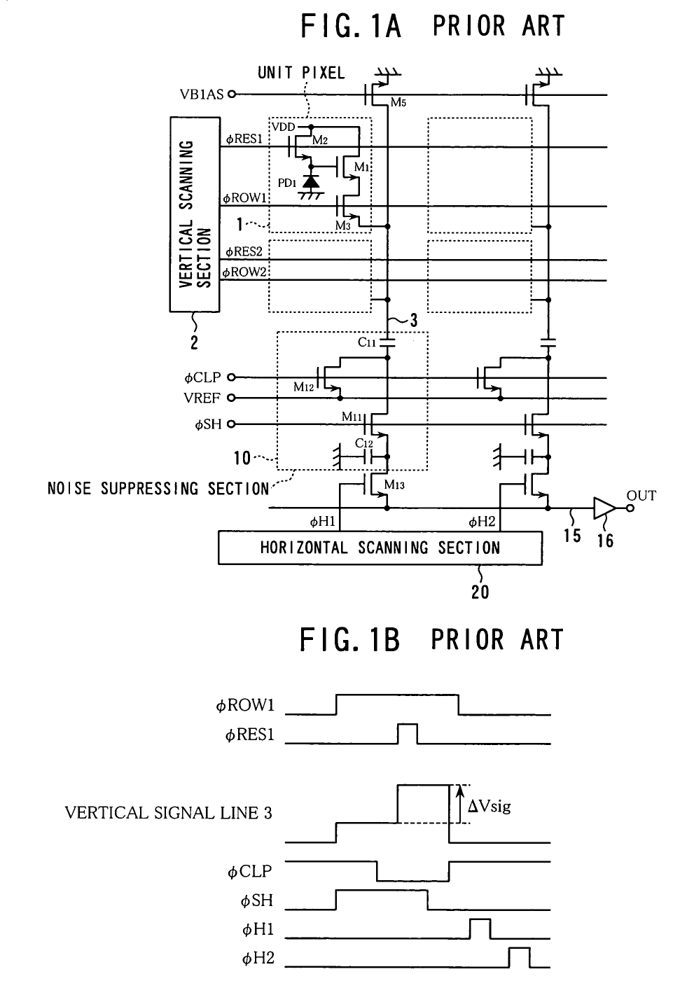

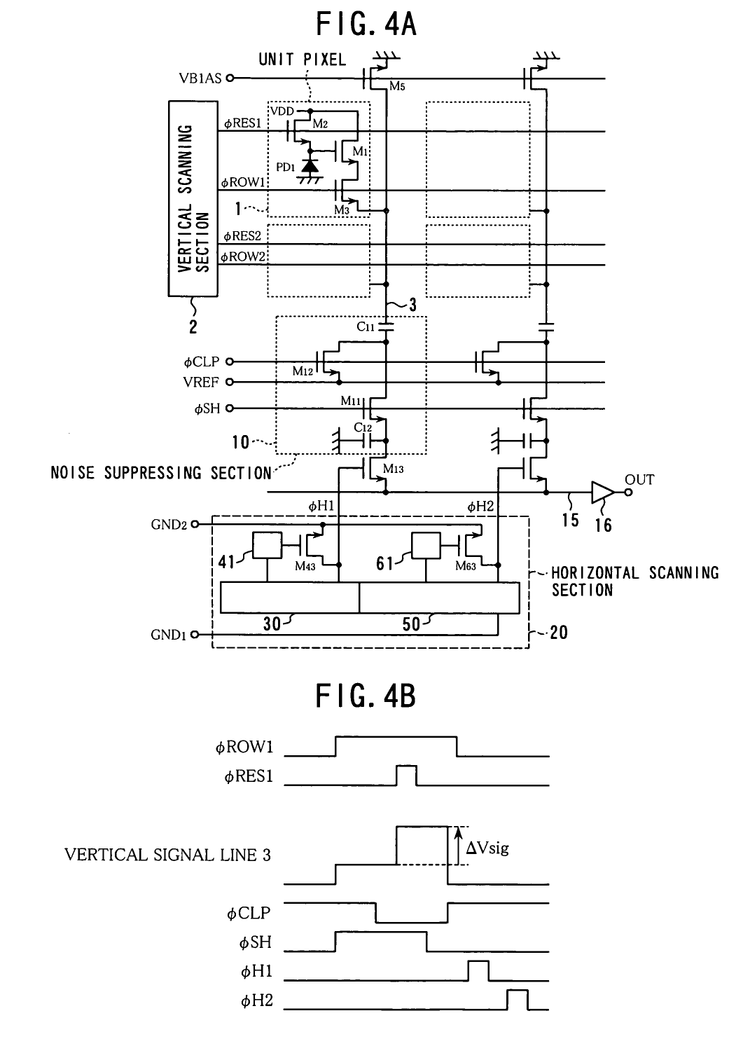

A first embodiment of the invention will now be described. FIG. 4A is a circuit diagram showing construction of a solid-state imaging apparatus using MOS image sensor according to the first embodiment of the invention. Although the construction of the solid-state imaging apparatus according to the first embodiment is different from the prior-art example shown in FIG. 1A only in the horizontal scanning section and construction of other portions thereof is similar to the prior-art example, it will be described below again. The solid-state imaging apparatus of this embodiment includes: unit pixels I each having a photodiode PD, serving as a photoelectric conversion section, an amplifying transistor M₁ for amplifying detection signals of the photodiode PD₁, a reset transistor M₂ for resetting detection signals of the photodiode PD₁, a row select transistor M₃ for selecting each row, and a pixel power supply VDD; a vertical scanning section 2 for driving a pixel section consisting of a plurality of unit pixels I that are arranged in a matrix (2×2 pixels in the illustrated example); a vertical signal line 3 for outputting detection signals of unit pixel 1; a bias transistor M₅ for causing a flow of constant current through the vertical signal line 3; a bias current adjusting voltage line VBIAS for determining a current value of the bias transistor; clamp capacitor C₁₁ connected to the vertical signal line 3; hold capacitor C₁₂ for retaining the amount of change in voltage of the vertical signal line 3; a sample hold transistor M₁₁ for connecting between clamp capacitor C₁₁ and hold capacitor C₁₂; a clamp transistor M₁₂ for clamping the clamp capacitor C₁₁ and hold capacitor C₁₂ to a predetermined voltage; a column select transistor M₁₃ for reading signals from the hold capacitor C₁₂ of each column, connected at one end terminal thereof to the hold capacitor C₁₂; a horizontal signal line 15 connected to the other end terminal of the column select transistor M₁₃; an output amplifier 16; and a horizontal scanning section 20 for driving the column select transistor M₁₃. The horizontal scanning section 20 will be described later in detail.

A fundamental operation of the solid-state imaging apparatus according to the first embodiment of the above described construction will now be described by way of a fundamental drive timing chart shown in FIG. 4B. When a row select pulse φROW1 of a first unit pixel row outputted from the vertical scanning section 2 is driven to H level, the row select transistor M₃ is turned ON so that signal voltage of the unit pixel 1 is-outputted onto the vertical signal line 3. At this time, the sample hold transistor M₁₁ and clamp transistor M₁₂ are turned ON by bringing clamp control pulse φCLP to H level and sample hold control pulse φSH to H level so as to fix the clamp capacitor C₁₁ and hold capacitor C₁₂ to a reference potential VREF.

Next, the connecting line between clamp capacitor C₁₁ and hold capacitor C₁₂ is brought into a floating state by driving clamp control pulse φCLP to L level to turn OFF the clamp transistor M₁₂. Subsequently, reset control pulse φRES1 of the first unit pixel row is driven to H level to turn ON the reset transistor M₂ so as to reset the detection signal of photodiode PD₁. Then, by driving the reset control pulse φRES1 back to L level again, the reset transistor M₂ is turned OFF. At this time, voltage change ΔVsig between before and after the resetting of photodiode PD₁ occurs on the vertical signal line 3 and accumulates at the clamp capacitor C₁₁ and the hold capacitor C₁₂ through sample hold transistor M₁₁.

Subsequently, the signal component of photodiode PD₁ is retained at the hold capacitor C₁₂ by driving the sample hold control pulse φSH to L level so as to turn OFF the sample hold transistor M₁₁.

Finally, the signal component retained at the hold capacitor C₁₂ is sequentially read out to the horizontal signal line 15 through the column select transistor M₁₃ by the means of horizontal select pulses φH1 and φH2 outputted from the horizontal scanning section 20 and is fetched from the output amplifier 16.

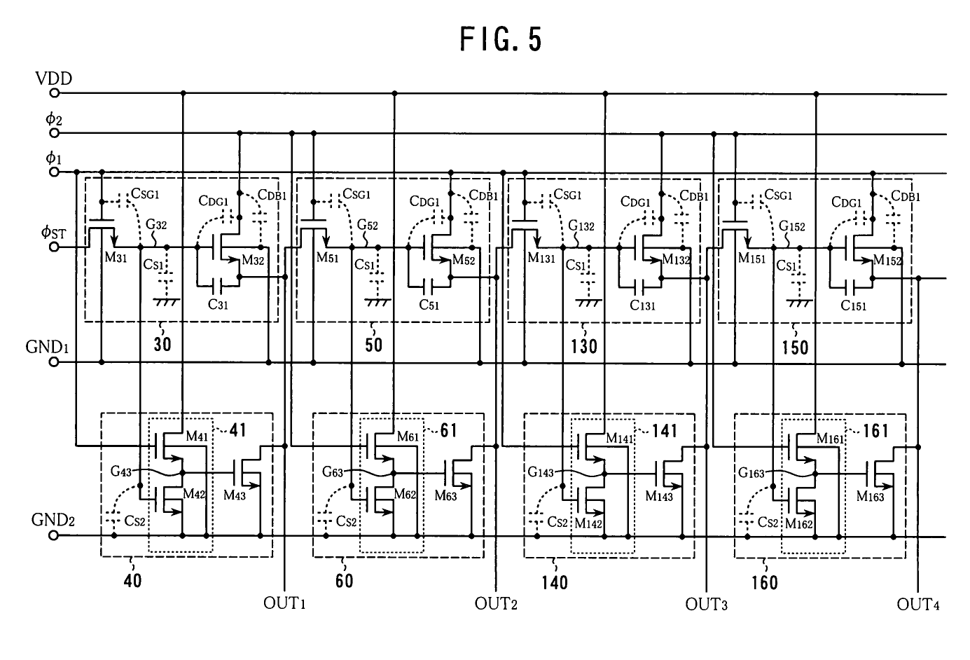

A detailed construction of the horizontal scanning section 20 will now be described by way of FIG. 5. The horizontal scanning section 20 is constituted only of NMOS transistors and capacitors. It includes: first scanning circuits 30, 130, . . . ; second scanning circuits 50, 150, . . . ; first reference potential fixing circuits 40, 140, . . . corresponding respectively to the first scanning circuits 30, 130, . . . ; and second reference potential fixing circuits 60, 160, . . . corresponding to the second scanning circuits 50, 150, . . . , respectively. One unit of scanning circuit section is then formed by the first and second scanning circuits 30, 50, and the corresponding first and second reference potential fixing circuits 40, 60. A plurality of the scanning circuit sections having similar construction are cascaded to form the horizontal scanning section 20.

The first scanning circuit 30 at the first stage includes: MOS transistor M₃₁ serving as a switch device to which signal (start pulse) from the input terminal φST is inputted; MOS transistor M₃₂ serving as a source follower for receiving at gate signals from the MOS transistor M₃₁ and for transmitting signals at source to an output line OUT₁ and to the second scanning circuit 50; and a bootstrap capacitor C₃₁ connected between gate and source of MOS transistor M₃₂. On the other hand, the second scanning circuit 50 at the first stage includes: MOS transistor M₅₁ serving as a switch device to which signals from the first scanning circuit 30 of the first stage are inputted; MOS transistor M₅₂ serving as a source follower for receiving at gate signals from the MOS transistor M₅₁ and for transmitting signals from source further to the first scanning circuit 130 of the next stage; and a bootstrap capacitor C₅₁ connected between gate and source of the MOS transistor M₅₂. The first and second scanning circuits 130, 150 of the next stage are also constructed similarly to the above described first and second scanning circuits 30, 50 of the first stage. A first ground line GND₁ is connected to the back gate of each component (MOS transistor) of the scanning circuits 30, 50, . . . , etc.

The first reference potential fixing circuit 40 corresponding to the first scanning circuit 30 of the first stage includes: a first control circuit 41 having MOS transistor M₄₂ which receives at gate signal (start pulse) from the input terminal φST and which is connected at source to a second ground line GND₂, and MOS transistor M₄₁ which is connected at source to the drain of the MOS transistor M₄₂ and at drain to a power supply line VDD; and MOS transistor M₄₃ serving as a switch device to the gate of which signals from the first control circuit 41 are inputted and which is connected at source to the second ground line GND₂ and at drain to the output line OUT₁. Further the second reference potential fixing circuit 60 corresponding to the second scanning circuit 50 includes: a second control circuit 61 having MOS transistor M₆₂ which receives at gate signals from the first scanning circuit 30 of the first stage and which is connected at source to the second ground line GND₂, and MOS transistor M₆₁ which is connected at source to the drain of the MOS transistor M₆₂ and at drain to the power supply line VDD; and MOS transistor M₆₃ serving as a switch device to the gate of which signals from the second control circuit 61 are inputted and which is connected at source to the second ground line GND₂ and at drain to the output line OUT₂. The first and second reference potential fixing circuits 140, 160 of the next stage are also constructed similarly to the above described first and second reference potential fixing circuits 40, 60 of the first stage. The second ground line GND₂ is connected to the back gate of each component (MOS transistor) of the reference potential fixing circuits 40, 60, . . . , etc.

The clock terminal φ1 is connected to the respective gates of MOS transistors M₃₁ and M₄₁ and to the drain of MOS transistor M₅₂, respectively, and the clock terminal φ2 is connected to the respective gates of MOS transistors M₅₁, M₆₁ and to the drain of MOS transistor M₃₂. Thus constructed scanning-circuit section constituted of the first and second scanning circuits 30, 50, and corresponding first and second reference potential fixing circuits 41, 61 serves as one unit which is repeatedly connected in sequence to form the horizontal scanning section 20.

It should be noted in FIG. 5 that: G₃₂, G₅₂, . . . are the gate lines of MOS transistors M₃₂, M₅₂, . . . ; G₄₃, G₆₃, . . . are the gate lines of MOS transistors M₄₃, M₆₃, . . . ; C_{S1} is parasitic capacitance not contributing to the bootstrap effect added to the gate lines G₃₂, G₅₂, . . . ; C_{S2} is parasitic capacitance not contributing to bootstrap effect, caused by gate of the MOS transistors M₄₂, M₆₂, . . . ; C_{SG1} is overlap capacitance between gate and source of MOS transistors M₃₁, M5₁, . . . ; C_{DG1} is overlap capacitance between gate and drain of MOS transistors M₃₂, M₅₂, . . . ; and C_{DB1} is junction capacitance between drain and substrate of MOS transistors M₃₂, M₅₂, . . . , etc.

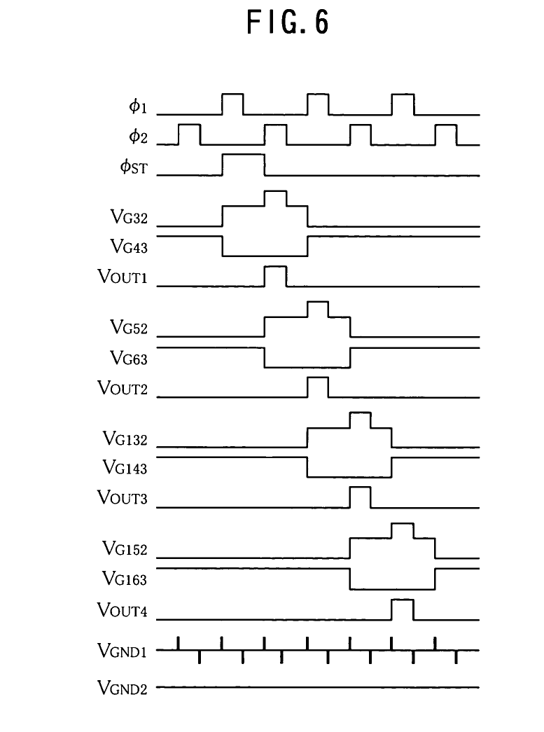

FIG. 6 is a timing chart for explaining a fundamental operation of the horizontal scanning section shown in FIG. 5. Signals (start pulse signal and control clock pulse signal) indicated by φST, φ1 and φ2 of FIG. 6, respectively, are given to the input terminal φST and clock terminals φ1, φ2 of FIG. 5. Here H level potential of signals φST, φ1 and φ2 is defined as V_{H}, and threshold value of all the MOS transistors as Vₜₕ.

First, when input terminal φST and clock terminal φ1 are driven to H level, MOS transistor M₃₁ becomes conductive. Since H level of the input terminal φST is thereby transmitted through MOS transistor M₃₁ so that charges are accumulated at the bootstrap capacitor C₃₁, potential at the gate line G₃₂ of MOS transistor M₃₂ becomes H level as indicated by V_{G32} of FIG. 6. Supposing H level potential of the gate line G₃₂ of MOS transistor M₃₂ at this time as V_{H}′:
V_{H}=V_{H}−Vₜₕ (5)

Further, MOS transistor M₃₂ becomes conductive due to the fact that potential V_{G32} at the gate line G₃₂ of MOS transistor M₃₂ is brought to H level. An L level of clock terminal φ2 is thereby outputted to potential V_{OUT1} of the output line OUT₁. At this time, since MOS transistor M₄₂ also becomes conductive, the gate line G₄₃ of MOS transistor M₄₃ is connected to the second ground line GND₂ as indicated by V_{G43} of FIG. 6. MOS transistor M₄₃ is thereby cut off.

Next, when clock terminal φ1 is changed to L level and clock terminal φ2 then becomes H level after changing input terminal φST to L level, potential V_{G32} of the gate line G₃₂ of MOS transistor M₃₂ rises by V_{A} as expressed in the following formula (6) through the bootstrap capacitor C₃₁.
V_{A}={C₃₁/(C₃₁+C_{S1}+C_{S2})}V_{H} (6)
where C_{S1} and C_{S2} are parasitic capacitance not contributing to the bootstrap effect, caused by the gates of MOS transistors M₃₂ and M₄₂. Accordingly, potential V_{G32} of the gate line G₃₂ of MOS transistor M₃₂ is:
V_{G32}=V_{H}′+{C₃₁/(C₃₁+C_{S1}+C_{S2})}V_{H} (7)

At this time, if:
V_{G32}−Vₜₕ≧V_{H} (8)

High level of the clock terminal φ2 is extracted at the source of MOS transistor M₃₂. Here, since potential V_{G43} of the gate line G₄₃ of MOS transistor M₄₃ is continuously connected to the second ground line GND₂, the transistor M₄₃ is in its cut-off state. Since the second ground line GND₂ is thereby disconnected from the output line OUT₁, it does not cause an adverse effect on the output line OUT₁. Accordingly, an identical pulse as clock terminal φ2 is fetched on the output line OUT₁ as indicated by V_{OUT1} of FIG. 6. At the same time, since MOS transistor M₅₁ becomes conductive in synchronization with high level of clock terminal φ2, charges are accumulated at the bootstrap capacitor C₅₁. For this reason, the potential of the gate line G₅₂ of MOS transistor M₅₂ becomes H level as indicated by V_{G52} of FIG. 6.

Next, when clock-terminal φ1 is driven to H level again, potential V_{G52} of the gate line G₅₂ of MOS transistor M₅₂ is raised by H-level potential V_{H} of clock terminal φ1 through the bootstrap capacitor C₅₁ so that H level of clock terminal φ1 is extracted at the source of MOS transistor M₅₂. Accordingly, an identical pulse as clock terminal φ1 is fetched on the output line OUT₂ as indicated by V_{OUT2} of FIG. 6.

Further, since the input terminal φST at this time is L level, potential V_{G32} of the gate line G₃₂ of MOS transistor M₃₂ becomes L level. MOS transistor M₄₂ is thereby brought into its cut-off state. On the other hand, since MOS transistor M₄₁ is conductive, potential V_{G43} of the gate line G₄₃ of MOS transistor M₄₃ becomes H level. MOS transistor M₄₃ thereby becomes conductive so that potential V_{OUT1} of the output line OUT₁ is connected to the second ground line GND₂.

Similarly, of the scanning circuit section at the next stage of FIG. 5, potentials at the gate line G₁₃₂ of MOS transistor M₁₃₂ of the first scanning circuit 130, gate line G₁₄₃ of MOS transistor M₁₄₃ of the corresponding first reference potential fixing circuit 140, output line OUT₃, gate line G₁₅₂ of MOS transistor M₁₅₂ of the second scanning circuit 150, gate line G₁₆₃ of MOS transistor M₁₆₃ of the corresponding second reference potential fixing circuit 160, and output line OUT₄ are as indicated by V_{G132}, V_{G143}, VOUT₃, V_{G152}, V_{G163} and VOUT₄ of FIG. 6, respectively.

Accordingly, at the horizontal scanning section of this circuit construction, H level signal of the input terminal φST is sequentially transmitted so that pulse is sequentially fetched from the output lines OUT₁, OUT₂, OUT₃ and OUT₄.

Further in thus constructed horizontal scanning, section, a current is caused to flow to the first ground line GND₁ at the rising/falling of clock pulse signal φ1 or φ2, through the junction capacitance C_{DB1} between drain and substrate of MOS transistors M₃₂, M₅₂, etc. Accordingly, spike-like noise is mixed as shown in FIG. 6 into potential V_{GND1} of the first ground line GND₁ at the rising/falling of clock pulse signal φ1 or φ2. However, since output lines OUTn, when not selected, are fixed to the potential of the second ground line GND₂, the output noise of the horizontal scanning section occurring in synchronization with the change in clock terminal φ1 or φ2 due to the first and second scanning circuits 30, 50, . . . , can be suppressed. In the solid-state imaging apparatus shown in FIG. 4A, therefore, the noise plunging into the horizontal signal line 15 through the column select transistor M₁₃ can be suppressed.

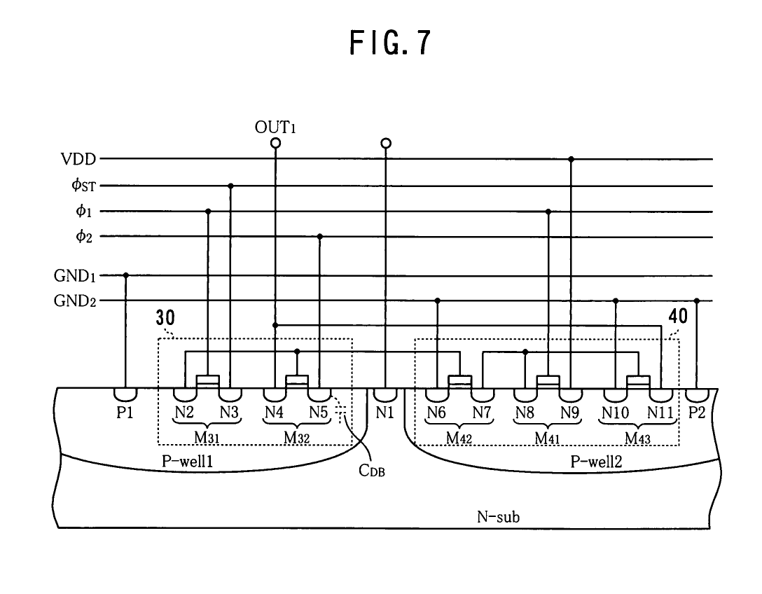

FIG. 7 is a conceptual drawing showing partially in section a portion of the case where the horizontal scanning section shown in FIG. 5 is formed on a single semiconductor substrate. Those components corresponding to those in FIG. 5 are denoted by identical reference numerals. The MOS transistors for transmitting signals are formed on n-type semiconductor substrate N-sub such that MOS transistors M₃₁ and M₃₂ of the first-stage first scanning circuit 30 of FIG. 5 are formed on a first p-type well region P-well1, and that MOS transistors M₄₁, M₄₂ and M₄₃ of the corresponding first reference potential fixing circuit 40 are formed on a second p-type well region P-well2. The potential at the first p-type well region P-well1 is fixed by the first ground line GND, through p-type diffusion layer P1, and the second p-type well region P-well2 is fixed to a reference potential by the second ground line GND₂ through p-type diffusion layer P2. An n-type diffusion layer N1 is formed between the first and second p-type well regions P-well1 and P-wll2 so that a fixed potential is given to the n-type semiconductor substrate N-sub through the n-type diffusion layer N1. It should be noted in FIG. 7 that N2, . . . , N11 are n-type diffusion layers for forming each MOS transistor, and C_{DB} is drain-substrate junction capacitance of MOS transistor.

In thus constructed horizontal scanning section, when clock pulse signal φI or φ2 is inputted to the clock terminal φ1, φ2 in the first scanning circuit 30 formed on the first p-type well region P-well1, a current is caused to flow to the first p-type well region P-well1 at the rising/falling of clock pulse through the drain-substrate junction capacitance C_{DB} of MOS transistor M₃₂ so that potential at the first p-type well region P-well1 is changed. The noise occurred at the first p-type well region P-well1 is cut off by the n-type semiconductor substrate N-sub and by the n-type diffusion layer N1 formed on the n-type semiconductor substrate N-sub and does not affect the second p-type well region P-well2. Accordingly, by connecting the second ground line GND₂ connected to the second p-type well region P-well2 to those output lines which are not being selected, the output noise of the horizontal scanning section occurring in synchronization with change at the clock terminal φ1 or φ2 can be suppressed. For this reason, in the solid-state imaging apparatus shown in FIG. 4A, noise plunging into the horizontal signal line 15 through the column select transistor M₁₃ can be suppressed.

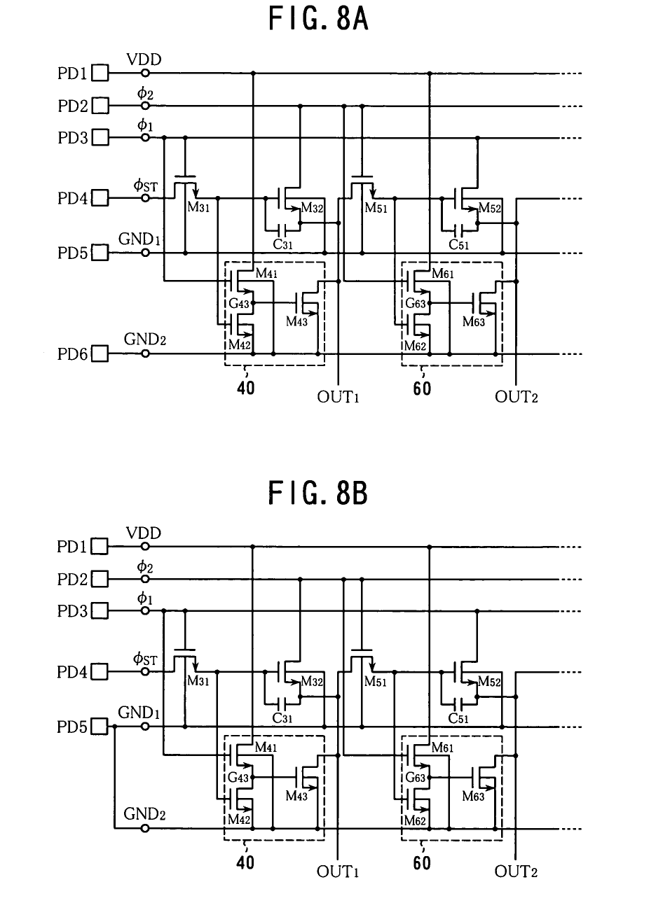

FIG. 8A schematically shows addition of pads for external input to the horizontal scanning section shown in FIG. 5. The power supply line VDD, clock terminals φ1 and φ2, input terminal φST, first and second ground lines GND₁, GND₂ are connected to the external input pads PD1 to PD6, respectively. A predetermined potential (not shown) is supplied from an external source to the external input pads PD1 to PD6.

In this manner, for the first and second ground lines GND₁, GND₂, by connecting an external source to the ground lines through different external input pads PD5, PD6, the first and second ground lines GND₁, GND₂ do not interfere with each other. For this reason, even when noise caused by the first and second scanning circuits 30, 50, . . . , in synchronization with change at clock terminal φ1 or φ2 is mixed into the first ground line GND₁, it does not affect the second ground line GND₂ on the side of the first and second reference potential fixing circuits. Accordingly, by connecting the second ground line GND₂ to those output lines which are not being selected, it is possible to suppress the output noise of the horizontal scanning section which occurs in synchronization with change at clock terminal φ1 or φ2. In the solid-state imaging apparatus shown in FIG. 4A, therefore, the noise plunging into the horizontal signal line 15 through the column select transistor M₁₃ can be suppressed.

Further as shown in FIG. 8B, also in the case where the first ground line GND₁ and the second ground line GND₂ are connected to each other in the vicinity of the external input pad PD5, the noise mixed into the first ground line GND₁ caused by the first and second scanning circuits 30, 50, . . . has relatively smaller effect in the vicinity of the pad and therefore does not affect too much the second ground line GND₂ on the side of the first and second reference potential fixing circuits. Accordingly, by connecting the second ground line GND₂ to those output lines which are not being selected, it is possible to suppress the output noise of the horizontal scanning section which occurs in synchronization with change at clock terminal φ1 or φ2. In addition in the case of this construction, since a fewer number of external input pads are used, an increase in chip area can be reduced.

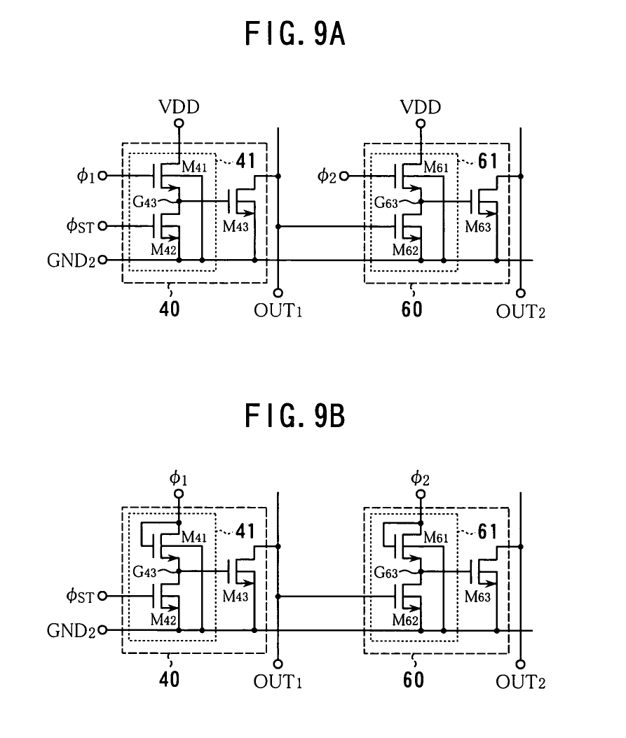

While the horizontal scanning section in the first embodiment has been described by way of construction shown in FIG. 5, the reference potential fixing circuits 40, 60, . . . thereof may, be constructed differently from the construction shown in FIG. 5. Shown in FIGS. 9A, 9B are modifications of the construction of the first and second reference potential fixing circuits 40, 60, etc. In operation of the case where the first and second reference potential fixing circuits 40, 60, . . . are constructed as shown in FIG. 9A, since MOS transistor M₄₂ becomes conductive when start pulse signal φST is driven to H level, the gate line G₄₃ of MOS transistor M₄₃ is connected to the second ground line GND₂. Accordingly, MOS transistor M₄₃ is brought into its cut-off state so that the second ground line GND₂ is disconnected from the output line OUT₁. When start pulse signal φST becomes L level and H level of clock pulse φ1 is inputted, MOS transistor M₄₂ is cut off. For this reason, since MOS transistor M₄₁ becomes conductive, potential at the gate line G₄₃ of MOS transistor M₄₃ is driven to H level. Accordingly, MOS transistor M₄₃ becomes conductive, and the output line OUT₁ is connected to the second ground line GND₂. In this manner, it is also possible with the construction shown in FIG. 9A to connect those output lines not being selected to the second ground line GND₂.

Also in the case where the first and second reference potential fixing circuits 40, 60, . . . are constructed as shown in FIG. 9B, those output lines not being selected can similarly be connected to the second ground line GND₂. As the above, similar effects and advantages as in the horizontal scanning section shown in FIG. 5 can be obtained also when the first and second reference potential fixing circuits 40, 60, . . . are constructed as shown in FIGS. 9A and 9B. In addition to the construction shown in FIGS. 9A and 9B, any other circuit construction where unselected output lines are connected to a ground line may be suitably used as the reference potential fixing circuits in the present embodiment.

### Embodiment 2

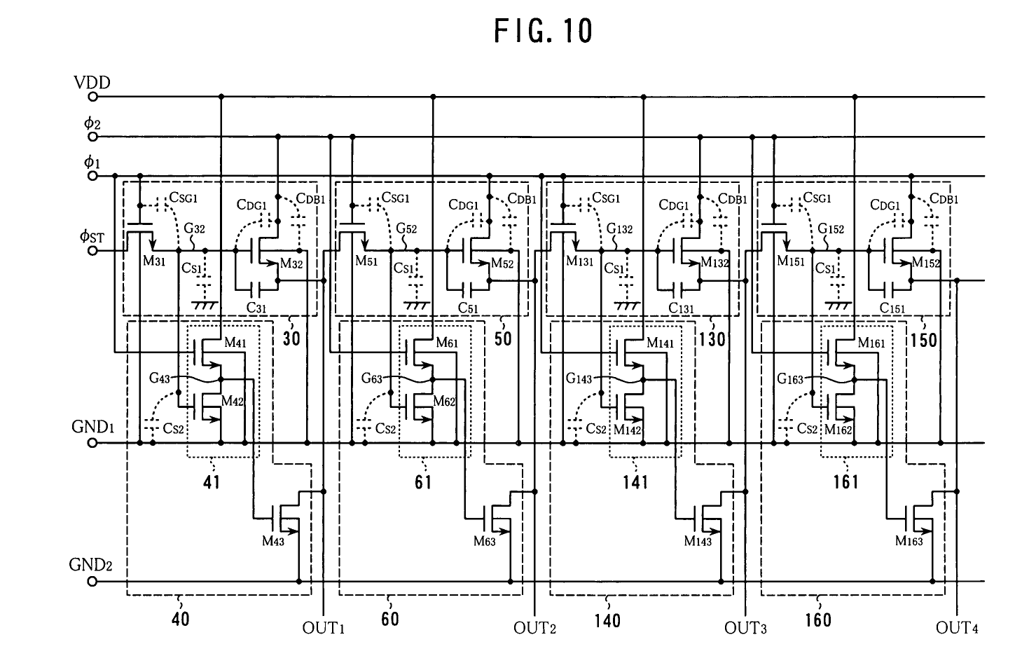

FIG. 10 is a circuit diagram showing construction of the horizontal scanning section of a solid-state imaging apparatus according to a second embodiment of the invention. It should be noted that the construction of the portions other than the horizontal scanning section is similar to the construction of the first embodiment shown in FIG. 4A and an illustration and description thereof will be omitted. The horizontal scanning section according to the second embodiment is also constituted only of NMOS transistors and capacitors similarly to the horizontal scanning section 20 according to the first embodiment shown in FIG. 5. It differs from the horizontal scanning section shown in FIG. 5 in the portion where back gates of MOS transistors M₄₁, M₆₁, . . . , and M₄₂, M₆₂, . . . , and sources of MOS transistors M₄₂, M₆₂, . . . of the first and second control circuits 41, 61, . . . of the first and second reference potential fixing circuits 40, 60, . . . are connected to the first ground line GND₁. The construction of other portions is similar to the horizontal scanning section of the first embodiment shown in FIG. 5 and those components corresponding to the horizontal scanning section shown in FIG. 5 are denoted by identical reference numerals. It should be noted that C_{SG1} is overlap capacitance between gate and source of MOS transistors M₃₁, M₅₁, . . . , and C_{DG1} is overlap capacitance between drain and gate of MOS transistors M₃₂, M₅₂, etc.

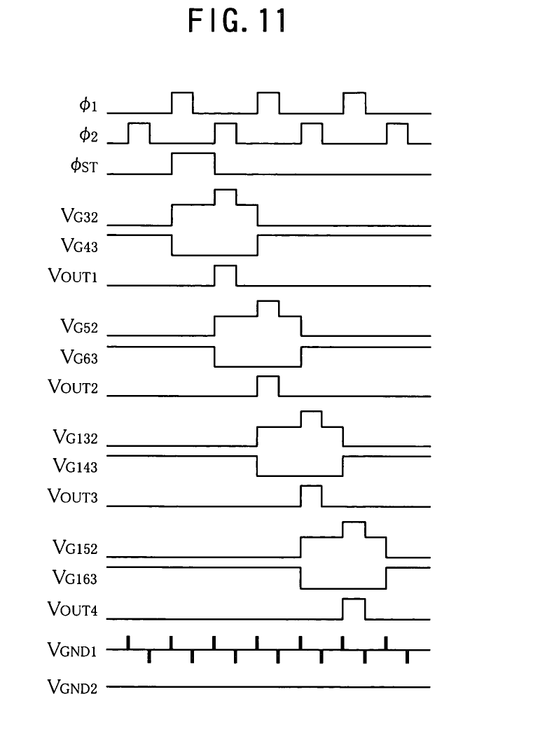

FIG. 11 is a timing chart showing a fundamental operation of the horizontal scanning section shown in FIG. 10. As for the operation where H level signal of the input terminal φST is sequentially transmitted to sequentially fetch pulse from the output lines OUT₁, OUT₂, OUT₃ and OUT₄, it is entirely similar to the operation described in the first embodiment. In the horizontal scanning section according to the embodiment shown in FIG. 10, an advantage of further suppressing noise mixed into the second ground line GND₂ is obtained in addition to the suppressing effect of the output noise which occurs in synchronization with change in clock terminal φ1 or φ2 due to the first and second scanning circuits 30, 50, etc. Particularly, in the second embodiment, since the first and second control circuits 41, 61, . . . of the first and second reference potential fixing circuits 40, 60, . . . are connected to the first ground line GND₁, noise synchronized with change in clock pulse φ1 or φ2 occurring through the gate-source overlap capacitance C_{SG1} of MOS transistors M₃₁, M₅₁, . . . or the drain-gate overlap capacitance C_{DG1} of MOS transistors M₃₂, M₅₂, . . . , and parasitic capacitance C_{S2} due to gate of MOS transistors M₄₂, M₆₂, . . . is mixed into the first ground line GND₁. Accordingly, noise mixed into the second ground line GND₂ is further suppressed. Since output line OUTn not being selected is connected to the second ground line GND₂, output noise of the horizontal scanning section occurring in synchronization with change in clock terminal φ1 or φ2 due to the first and second scanning circuits 30, 50, . . . can be further suppressed. For this reason, in the solid-state imaging apparatus of the construction similar to the solid-state imaging apparatus shown in the first embodiment of FIG. 4A with the exception of the horizontal scanning section, it is possible to further suppress noise which plunges into the horizontal signal line 15 through the column select transistor M₁₃.

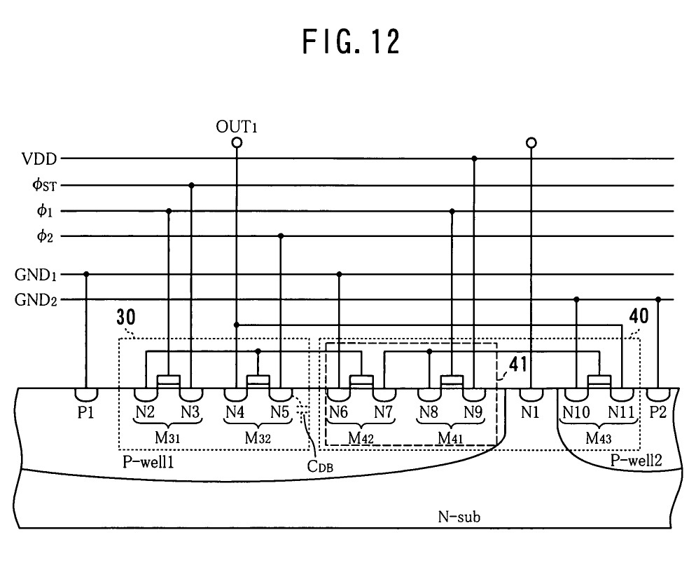

FIG. 12 is a conceptual drawing showing partially in section the construction in the case where the horizontal scanning section according to the second embodiment shown in FIG. 10 is formed on a single semiconductor substrate. Those components corresponding to those in FIG. 10 are denoted by identical reference numerals. MOS transistors M₃₁ and M₃₂ of the first scanning circuit 30 of the first stage, and MOS transistors M₄₁ and M₄₂ of the corresponding first control circuit 41 are formed on a first p-type well region P-well1, and only the MOS transistor M₄₃ of the corresponding first reference potential fixing circuit section 40 is formed on a second p-type well region P-well2. A reference potential is supplied to the first p-type well region P-well1 from the first ground line GND₁ through p-type diffusion layer P1, and the second p-type well region P-well2 is fixed to a reference potential by the second ground line GND₂ through p-type diffusion layer P2. An n-type diffusion layer N1 is formed between the first and second p-type well regions P-well1 and P-well2 so as to give a fixed potential to the n-type semiconductor substrate N-sub through the n-type diffusion layer N1. It should be noted in FIG. 12 that N2, . . . , N11 refer to n-type diffusion layer for forming each MOS transistor, and C_{DB} refers to the drain-substrate junction capacitance of MOS transistor.

In such construction, noise synchronized with change in clock pulse φ1 or φ2 due to the first scanning circuit 30 and first control circuit 41 is mixed into the first p-type well region P-well1 so that the second p-type well region P-well2 is not affected. Accordingly, by connecting those output lines not being selected to the second ground line GND₂ which is connected to the second p-type well region P-well2, the output noise of the horizontal scanning section occurring in synchronization with change of clock terminal φ1 or φ2 can be suppressed. For this reason, in the solid-state imaging apparatus constructed similarly to the solid-state imaging apparatus shown in FIG. 4A, a further suppression is possible of the noise plunging into the horizontal signal line 15 through the column select transistor M₁₃.

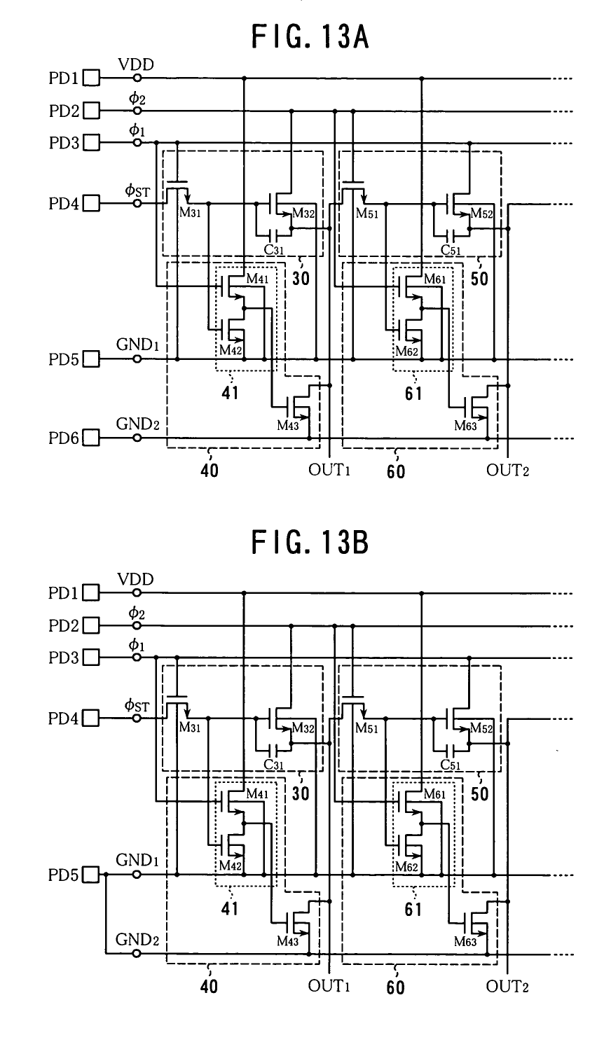

FIG. 13A schematically shows the manner where pads for external input are added to the horizontal scanning section according to the second embodiment shown in FIG. 10. By thus connecting the first and second ground-lines GND₁, GND₂ to different external input pads PD5 and PD6 so as to connect the ground lines to an external source through the external input pads PD5 and PD6, the first and second ground lines GND₁, GND₂ do not interfere with each other. Thus the noise mixed into the first ground line GND₁ due to the first and second scanning circuits does not affect the second ground line GND₂. Accordingly, by connecting the second ground line GND₂ to those output lines not being selected, the output noise of the horizontal scanning section occurring in synchronization with change of clock terminal φ1 or φ2 can be suppressed. For this reason, in the solid-state imaging apparatus constructed similarly to the solid-state imaging apparatus shown in FIG. 4A, a further suppression is possible of the noise plunging into the horizontal signal line 15 through the column select transistor M₁₃.

Further as shown in FIG. 13B, also in the case where the first ground line GND₁ and second ground line GND₂ are connected to each other near the external input pad PD₅, the noise mixed into the first ground line GND₁ caused by the first and second scanning circuits has relatively smaller effect in the vicinity of the pad and therefore does not affect the second ground line GND₂. Accordingly, by connecting the second ground line GND₂ to those output lines not being selected, it is possible to suppress the output noise of the horizontal scanning section which occurs in synchronization with change of clock terminal φ1 or φ2. In addition, in the case of this construction, since a construction with a fewer number of input pads can be used, an increase in chip-area can be reduced.

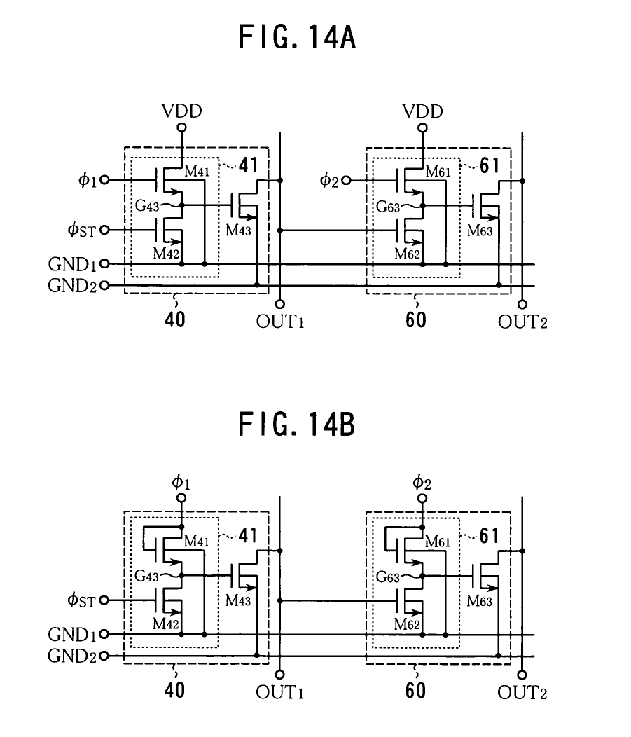

While the horizontal scanning section in the second embodiment has been described by way of construction shown in FIG. 10, it is also possible to use construction other than that shown in FIG. 10 as the first and second reference potential fixing circuits 40, 60, . . . thereof. Shown in FIGS. 14A and 14B are modifications of the construction of the first and second reference potential fixing circuits 40, 60, etc. In the case where the first and second reference potential fixing circuits 40, 60, . . . are constructed as shown in FIG. 14A, since MOS transistor M₄₂ becomes conductive when start pulse signal fST is driven to H level, the gate line G₄₃ of MOS transistor M₄₃ is connected to the first ground line GND₁. Accordingly, MOS transistor M₄₃ is brought into its cut-off state so that the first ground line GND₁ is disconnected from the output line OUT₁. When start pulse signal φST is driven to L level and H level of clock pulse φ1 is inputted, MOS transistor M₄₂ is cut off. For this reason, since MOS transistor M₄₁ becomes conductive, potential at the gate line G₄₃ of MOS transistor M₄₃ is driven to H level. Accordingly, MOS transistor M₄₃ becomes conductive, and the output line OUT₁ is connected to the second ground line GND₂. In this manner, those output lines not being selected can be connected to the second ground line GND₂ also with the construction shown in FIG. 14A.

Also in the case where-the first and second reference potential fixing circuits 40, 60, . . . are constructed as shown in FIG. 14B, those output lines not being selected can similarly be connected to the second ground line GND₂. As has been shown, similar effects and advantages as of the horizontal scanning section shown in FIG. 10 can be obtained also when the first and second reference potential fixing circuits 40, 60, . . . are constructed as shown in FIGS. 14A and 14B. In addition to the construction shown in FIGS. 14A and 14B, any other circuit construction where those output lines not being selected are connected to a ground line may be suitably used as the reference potential fixing circuits in the present embodiment.

In the above embodiments, while the horizontal scanning section has been described as having the construction of FIG. 5 or 10, the above described construction of the horizontal scanning section can also be applied to the construction of a vertical scanning section in the solid-state imaging apparatus according to the invention. Thereby it becomes possible to reduce output noise of the-vertical scanning section.

As has been described by way of the above embodiments, according to the first aspect of the invention, the mixing of noise occurred at the above described scanning circuit at least into the output of the second scanning section of the first and second scanning sections can be suppressed. For this reason, it is possible to achieve a solid-state imaging apparatus where noise plunging into the horizontal signal line from the second scanning section is reduced so as to improve signal quality. According to the second aspect, the mixing of noise occurred at the above described scanning circuit at least into the output of the second scanning section of the first and second scanning sections can be suppressed. For this reason, noise plunging into the horizontal signal line from the second scanning section is reduced so as to improve signal quality thereof. In addition, since the transistors included in the construction are composed solely of a one conducting type, the process thereof can be simplified.

According to the third aspect of the invention, the first and second source followers and the first and second switch devices in the first or second scanning section are connected to the first reference potential line. For this reason, noise due to the first and second control pulses becomes smaller on the second reference potential line for fixing those output lines which are not being selected. For this reason, since output noise can be suppressed at least at the second scanning section of the first and second scanning sections, noise plunging into the horizontal signal line through the-second scanning section is reduced and the signal quality thereof is improved.

According to the fourth aspect of the invention, since noise occurring through a well due to the first and second scanning circuits in the solid-state imaging apparatus according to the third aspect can be prevented from mixing into the second reference potential line for fixing those output lines not being selected, noise mixed into the second reference potential line for fixing the unselected output lines becomes smaller. Accordingly, since-output noise is suppressed at least at the second scanning section of the first and second scanning sections, noise plunging into the horizontal signal line from the second scanning section is reduced and the signal quality thereof is improved.

According to the fifth aspect of the invention, since only the third and fourth switch devices are connected to the second reference potential line for fixing those output lines not being selected in the scanning section, noise occurring due to the first and second control pulses becomes even more smaller on the second reference potential line. Accordingly, since output noise can be suppressed at least at the second scanning section of the first and second scanning sections, noise plunging into the horizontal signal line from the second scanning section is reduced and the signal quality thereof is improved.

According to the sixth aspect of the invention, since noise occurring through a well caused by the first and second scanning circuits, and the first and second control circuits in the solid-state imaging apparatus according to the third aspect can be prevented from mixing into the second reference potential line for fixing those output lines not being selected, noise mixed into the second reference potential line for fixing the unselected output lines becomes smaller. Accordingly, since output noise can be suppressed at least at the second scanning section of the first and second scanning sections, noise plunging into the horizontal signal line from the second scanning section is reduced and the signal quality thereof is improved.

According to the seventh aspect of the invention, even when noise is mixed into the first reference potential line in the second scanning section of the first and second scanning sections; the second reference potential line for fixing those output lines not being selected is not affected by noise occurring through an external impedance component connected to pad. Thus noise mixed into the second reference potential line for fixing the unselected output lines becomes smaller. Accordingly, since output noise can be suppressed at least at the second scanning section of the first and second scanning sections, noise plunging into the horizontal signal line from the second scanning section is reduced and the signal quality thereof is improved.

According to the eighth aspect of the invention, even when noise is mixed into the first reference potential line in the second scanning section of the first and second scanning sections, the second reference potential Line for fixing those output lines not being selected is not affected too much by noise occurring through an external impedance component connected to pad. Thus noise mixed into the second reference potential line for fixing the unselected output lines becomes smaller. Accordingly, since output noise can be suppressed at least at the second scanning section of the first and second scanning sections, noise plunging into the horizontal signal line from the second scanning section is reduced and the signal quality thereof is improved. In addition, since construction with fewer pads is possible, an increase in chip area can be reduced.

What is claimed is:

1. A solid-state imaging apparatus comprising:
a pixel section having a plurality of pixels disposed two-dimensionally in rows and columns, each pixel containing a photoelectric conversion section and an amplifying section for amplifying output of the photoelectric conversion section to output pixel signals;
a first scanning section for selecting a row to be read out of the pixel section;
a noise suppressing section for effecting pixel-by-pixel noise suppression of the pixel signals;
a second scanning section for selecting a column to be read out of said pixel section to cause the pixel signals processed through said noise suppressing section be outputted from a horizontal signal line;
a first reference potential line for supplying a reference potential; and
a second reference potential line separate from the first reference potential line;
wherein at least the second scanning section of said first and second scanning sections is constituted of a plurality of units in cascade connection, each one unit comprising:
a scanning circuit having a function device group formed on a first well region connected to said first reference potential line, for supplying signals for effecting said selection process to said pixel section through an output line; and
a reference potential fixing circuit having a switch device connected at one end to said output line and at the other end to said second reference potential line, and a control circuit for controlling the switch device.

2. The solid-state imaging apparatus according to claim 1, wherein said scanning circuit includes transistors in said function device group, the transistors being solely of a one conducting type.

3. The solid-state imaging apparatus according to claim 1, wherein said scanning circuit comprises:
a first scanning circuit having a first switch device connected at one end to said output line of preceding one of said units with connection at the other end thereof being controlled by a first control pulse, a first source follower connected at gate to the other end of the first switch device with receiving at the drain a second control pulse having a phase different from said first control pulse and connected at source to a first output line, and a first capacitance component connected between gate and source of the first source follower; and
a second scanning circuit having a second switch device connected at one end to the source of said first source follower with connection at the other end thereof being controlled by said second control pulse, a second source follower connected at gate to the other end of the second switch device with receiving at the drain the first control pulse and connected at source to a second output line and to the one end of said first switch of succeeding one of the units, and a second capacitance component connected between gate and source of the second source follower; and wherein said reference potential fixing circuit comprises:
a first reference potential fixing circuit having a third switch device serving as said switch device connected at one end to said first output line and at the other end to the second reference potential line, and a first control circuit serving as said control circuit for controlling the third switch device in accordance with a source output level of the second source follower of said preceding unit; and
a second reference potential fixing circuit having a fourth switch device serving as said switch device connected at one end to said second output line and at the other end to said second reference potential line, and a second control circuit serving as said control circuit for controlling the fourth switch device in accordance with level of signals supplied from the source of said first source follower.

4. The solid-state imaging apparatus according to claim 3, wherein said first and second reference potential fixing circuits are formed on a second well region connected to said second reference potential line, separate from said first well.

5. The solid-state imaging apparatus according to claim 3, wherein said first and second control circuits are formed on said first well region.

6. The solid-state imaging apparatus according to claim 3, wherein said third and fourth switch devices are formed on a second well region connected to said second reference potential line, separate from said first well.

7. The solid-state imaging apparatus according to claim 3, wherein said first reference potential line and said second reference potential line are connected to different pads from each other.

8. The solid-state imaging apparatus according to claim 3, wherein said first reference potential line and said second reference potential line are connected to the same one pad in the vicinity of the pad.
